(19) United States
(12) Patent Application Publication
(10) Pub. No.: US 2004/0097204 A1
(43) Pub. Date: May 20, 2004

(54) Multi-subscriber detection using a rake receiver structure

(76) Inventors: Peter Jung, Otterberg (DE); Jorg Plechinger, Munchen (DE); Michael Schneider, Munchen (DE); Tideya Kella, Munchen (DE); Thomas Ruprich, Munchen (DE)

Correspondence Address: LERNER AND GREENBERG, PA, P O BOX 2480, HOLLYWOOD, FL, 33022-2480, US

(21) Appl. No.: 10/712,693

(22) Filed: Nov. 13, 2003

Related U.S. Application Data
(63) Continuation of application No. PCT/DE02/01697, filed on May 10, 2002.

(30) Foreign Application Priority Data
May 14, 2001 (DE) 101 23 333.7

(51) Int. Cl. H04B 1/00; H03D 1/00; H04L 27/06

(52) U.S. Cl. 455/132; 375/340; 455/561

(57) ABSTRACT

In a method for multi-subscriber detection using a RAKE receiver structure, one or more RAKE fingers is or are deactivated in order to reduce the power consumption of the RAKE receiver structure during operation. This makes it possible to considerably reduce the signal processing complexity for equalization, since only those energy-relevant areas of the channel impulse response which are required to ensure a required quality of service (QoS) are included in the JD algorithm.

### CROSS-REFERENCE TO RELATED APPLICATION

This application is a continuation of copending International Application No. PCT/DE02/01697, filed May 10, 2002, which designated the United States and was not published in English.

### BACKGROUND OF THE INVENTION

1. Field of the Invention

The invention relates to a method for reducing signal processing complexity for multi-subscriber detection using a RAKE receiver structure, and to a RAKE receiver structure for multi-subscriber detection with reduced signal processing complexity.

The use of multi-subscriber detection techniques, which is also referred to as joint detection (JD) equalization, on the one hand allows high payload data rates in mobile radio systems, while on the other hand JD equalization methods require an extremely high level of signal processing complexity. In the case of code division multiple access (CDMA) systems, for example in the case of universal mobile telecommunications system (UMTS), the high payload data rates result from the capability to use short spreading codes and thus to achieve high symbol rates. The extremely high signal processing complexity for JD equalization is based on the principle of operation of JD equalization. This includes the interference that is caused by other active mobile radio subscribers (which is referred to as intracell interference) being eliminated by explicit detection of the subscriber signals. Therefore, the interference can be reduced considerably, or in the ideal case can be eliminated, by making use of the fact that the interference that is caused by the activities of other subscribers is deterministic (not noise).

The extremely high signal processing complexity has until now made it virtually impossible to use JD algorithms in mobile stations. The signal processors that are currently used in mobile stations are not powerful enough for known JD algorithms. At the moment, their replacement by more powerful (and thus more expensive) signal processors likewise appears not to be feasible, since this would result in an excessively high power consumption.

In addition to the simultaneous activity of two or more mobile radio subscribers, one further special feature of mobile radio is that radio signals are subject to multi-path propagation. Therefore a number of received versions of a signal occur at the receiver, as a result of reflection, scatter and diffraction of the transmitted radio signal on various obstructions in the propagation path, and these different versions are shifted in time with respect to one another and are attenuated to different extents. The principle of operation of a RAKE receiver is based on evaluating these versions of the received signal (paths) separately, and then superimposing them with the correct time. The expression RAKE in this case provides an illustrative description of the structure of a receiver such as this, with the “tines” of the rake representing the RAKE fingers, and the “handle” of the rake representing the superimposed received signal that is produced on the output side.

RAKE receivers allow excellent detection results to be achieved. However, for mobile radio purposes, their high power consumption is a problem, and is caused by the parallel structure of the RAKE fingers and the fact that this multiplies the signal processing complexity.

One method for JD equalization is described in detail on pages 188 to 215 as well as 315 to 318 of the book entitled “Analyse und Entwurf digitaler Mobilfunksysteme” [Analysis and Design of Digital Mobile Radio Systems] by P. Jung, B. G. Teubner Verlag,. Stuttgart 1997. This method is referred to as block JD equalization since the data that is transmitted within a data block from all the subscribers is reconstructed in the receiver by solving a linear equation system that describes the transmission of the entire data block. The linear equation system is in this case solved by what is referred to as Cholesky decomposition of the matrix that represents the equation system.

Various RAKE receivers are described on pages 658 to 684 of the book entitled “Nachrichtenübertragung” [Message Transmission] by K. D. Kammeyer, B. G. Teubner Verlag, Stuttgart, 1996, 2nd Edition. It is mentioned there that a weighted path summation is advantageous in the RAKE receiver, provided that the overall received energy is not distributed uniformly between the detected paths (that is to say the fingers of the RAKE receiver). This admittedly makes it possible to reduce the noise, but not the power consumption, of the RAKE receiver.

### SUMMARY OF THE INVENTION

It is accordingly an object of the invention to provide multi-subscriber detection using a RAKE receiver structure that overcome the above-mentioned disadvantages of the prior art devices and method of this general type, which contributes to reducing the signal processing complexity for multi-subscriber detection. A further aim of the invention is to provide a receiver that is suitable for multi-subscriber detection and has reduced signal processing complexity.

With the foregoing and other objects in view there is provided, in accordance with the invention, a method for multi-subscriber detection using a RAKE receiver structure having a fixed time offset between the RAKE fingers. The method includes mapping a multi-subscriber system matrix onto the RAKE receiver structure by allocating each of the RAKE fingers to a defined section of the multi-subscriber system matrix, and deactivating at least one of the RAKE fingers for reducing power consumption of the RAKE receiver structure during operation.

The deactivation of one or more RAKE fingers in the RAKE receiver structure which is used for multi-subscriber detection makes it possible to considerably reduce the signal processing complexity for equalization, since only those energy-relevant areas of the channel impulse response which are required to ensure a required quality of service (QoS) are included in the JD algorithm.

As will be explained in more detail in the following text, multi-subscriber detection is based on the solution of a linear equation system that is defined by a JD system matrix. According to the invention, the JD system matrix is mapped onto the structure of a RAKE receiver so that each RAKE finger is associated with a defined section of the matrix. When one RAKE finger is deactivated, the section of the system matrix is no longer considered, that is to say the system matrix (and thus the linear equation system to be solved for JD equalization) is reduced in size. This results in a decrease in the power consumption by deactivation of one RAKE finger.

One advantageous exemplary embodiment of the method according to the invention is characterized by the steps of measurement of the energy levels of the signals that are associated with the RAKE fingers and determination of the RAKE finger or fingers to be deactivated in dependence on the measured energy levels. Therefore the selection of the fingers that are to be deactivated or switched off is preferably carried out as a function of the energy levels of the signals that are processed in the individual RAKE fingers.

In addition to the selection process, it is necessary to define the number of RAKE fingers that can be deactivated. The number of fingers to be deactivated is preferably determined as a function of an assessment variable, for example the bit error rate (BER), which is characteristic of the quality of service of the detected signal. In this case, a value is determined for the assessment variable, and the number of active RAKE fingers is determined as a function of the determined value of the assessment variable.

The method according to the invention is preferably used in a mobile station in a mobile radio system, where the requirements to minimize the power consumption of the receiver are particularly stringent.

A further advantageous refinement of the method according to the invention is for zero forcing (ZF) JD equalization or minimum mean square error (MMSE) JD equalization to be carried out on the received data signals. As already mentioned, the reduction in the computation complexity for ZF or MMSE equalization is achieved by deactivation of one or more RAKE fingers.

A RAKE receiver structure according to the invention has a device for deactivating one or more RAKE fingers in order to reduce the power consumption during multi-subscriber detection operation.

In this case, the RAKE receiver structure according to the invention preferably has a device for measuring the energy levels of the signals that are associated with the RAKE fingers, as well as a device for determining the RAKE finger or fingers to be deactivated, in dependence on the measured energy levels.

In accordance with an added feature of the invention, a device is provided for determining an assessment variable that is characteristic of a quality of service of a detected signal. In addition, a device is provided for determining which of the RAKE fingers are to be deactivated, in dependence on a determined assessment variable.

In accordance with a further feature of the invention, a device is provided for calculating multi-subscriber equalizer coefficients for ZF equalization or for MMSE equalization of received signals.

Other features which are considered as characteristic for the invention are set forth in the appended claims.

Although the invention is illustrated and described herein as embodied in multi-subscriber detection using a RAKE receiver structure, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic illustration of an air interface of a mobile radio system with a mobile station and a base station;

FIG. 2 is a simplified block diagram to explain the structure of a baseband section of a RAKE receiver structure according to the invention;

FIGS. 3A and 3B are illustrations for explaining the way in which a RAKE finger is switched off according to the invention for multi-subscriber equalization in the RAKE receiver structure; and

FIG. 4 is a graph illustrating a bit error rate (BER), determined from a simulation, compared to a signal-to-noise ratio (SNR) for a different number of active RAKE fingers.

### DESCRIPTION OF THE PREFERRED EMBODIMENTS

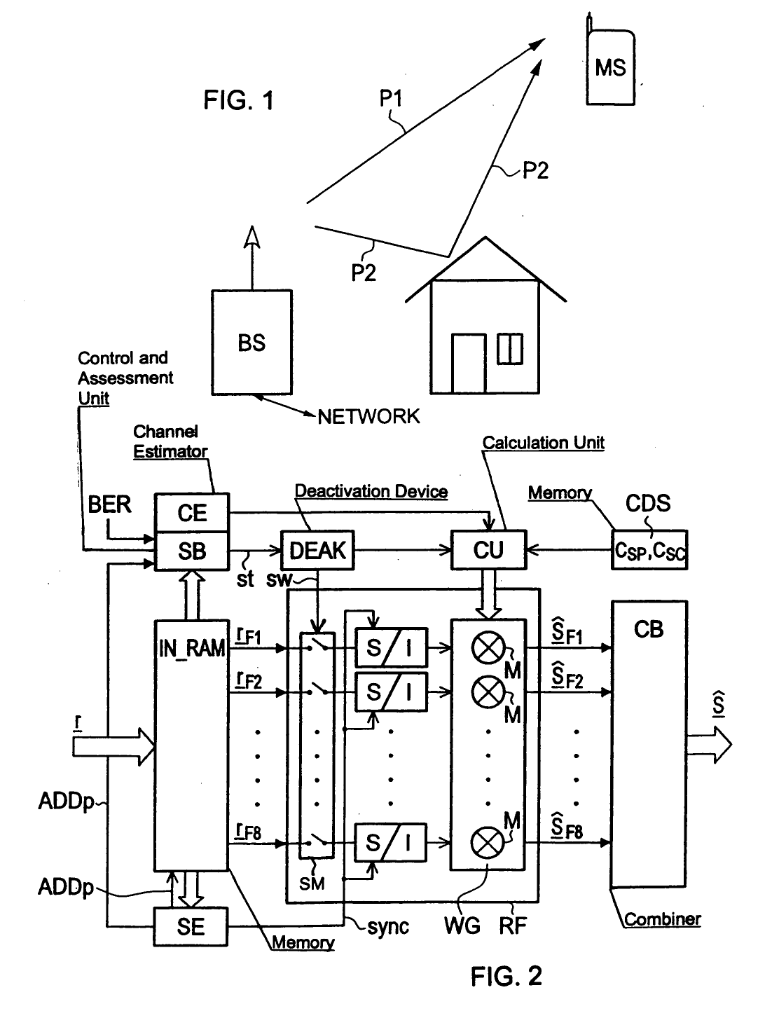

Referring now to the figures of the drawing in detail and first, particularly, to FIG. 1 thereof, there is shown a schematic illustration of an air interface of a cellular mobile radio system. A mobile station MS that is associated with one specific subscriber is connected by radio to a base station BS. The illustration shows the downlink path, that is to say the connection from the base station (BS) (transmitter) to the mobile station MS (receiver).

The radio link is subject to multipath propagation, that is to say a radio signal which is transmitted from the base station BS can reach the mobile station MS on different transmission routes or paths P1, P2 through the air interface. Owing to reflection, scatter and diffraction, the individual paths P1, P2 have different transmission behaviors, and may be regarded as independent transmission channels. In particular, the transmission channels (paths through the air interface) have different delay times and different signal attenuation levels. The former results in versions of the received signal being received at different times at the mobile station MS, while the latter results in that these versions of the received signal have different energy levels.

A mobile radio system is considered which uses CDMA spread coding of the subscriber signals. In the case of CDMA spread coding, a CDMA spreading code is applied to each transmitted symbol at the transmitter end, and makes it possible to distinguish the symbol from the symbols of other subscribers (or, in a more general form, other “logical” channels). The application of a CDMA spreading code to a data symbol that is to be transmitted can be carried out, for example, by multiplying the symbol by the CDMA spreading code sequence that represents the CDMA spreading code. The elements of the CDMA spreading code sequence are referred to as chips.

In the case of UMTS, a time duration Tc of one chip is approximately 0.26 μs, that is to say the chip rate 1/Tc is approximately 3.84 MHz. The number of chips per symbol is referred to as the spread factor Q. Q is variable, such that Q=Ts/Tc, where Ts denotes the symbol time duration.

FIG. 2 shows a baseband section of a RAKE receiver structure according to the invention. The baseband section has an input memory IN_RAM to which a signal containing a stream of complex data r is supplied. The input memory IN_RAM provides temporary storage of the data r.

A search and synchronization unit SE accesses the data r stored in the input memory IN_RAM and, on the basis of an evaluation of pilot symbols (that is to say symbols which are known to the receiver) which are contained in it and have already been separated from the data signal, identifies the data structure of different signal versions, which have been received via different paths P1, P2, and the time offsets between the signal versions.

Path information ADD_{P}, which is determined by the search and synchronization unit SE, relating to the occurrence and the number of different signal versions is supplied to the input memory IN_RAM, and synchronization information sync is supplied to a RAKE finger section RF in the RAKE receiver.

Furthermore, a control and assessment unit SB accesses the input memory IN_RAM. The control and assessment unit SB is also supplied with the path information ADD_{P}. The control and assessment unit SB outputs a control signal st, which is supplied to a deactivation device DEAK. The deactivation device DEAK then produces a switching signal sw that is passed to the RAKE finger section RF. Furthermore, the deactivation device DEAK signals information, which corresponds to the switching signal sw, to a calculation unit CU.

The calculation unit CU is used to calculate equalizer coefficients. For this purpose, it is also connected to a channel estimator CE, which supplies the calculation unit CU with continuously updated channel information, for example in the form of channel coefficients (that is to say the channel impulse response in discrete form).

The spreading codes C_{SP} and scrambling codes C_{SC} that are available in the mobile radio system are stored in a code memory CDS. The code elements of these codes are chips. These codes are made available to the calculation unit CU, in order to calculate the equalizer coefficients.

On the input side, the RAKE finger section RF has a switching device SM, by which RAKE fingers that are disposed downstream from the switching device SM in the signal path can be selectively activated and deactivated as a function of the switching signal sw. The switching device SM is illustrated in a more or less symbolic manner in FIG. 2, in the form of a series of switches, although the individual RAKE fingers can also be activated and deactivated by other hardware measures.

Synchronization units are disposed in the signal paths downstream from the switching device SM. The synchronization units are used for synchronization of the individual RAKE fingers and for this purpose are formed, for example, from a buffer store S and an interpolator I.

A weighting unit WG is provided in the signal path downstream from the synchronization units. The weighting unit WG contains an array of multipliers M, by which the individual RAKE finger signals are subjected to multi-subscriber equalization by multiplying them by equalizer coefficients. The weighting unit WG emits output signals ŝ_{F1}, ŝ_{F2}, . . . , ŝ_{F8} which have been JD-equalized on a RAKE-finger-specific basis. The output signals ŝ_{F1}, ŝ_{F2}, . . . , ŝ_{F8} are combined in the normal manner by a combiner CB (for example a maximum ratio combiner:MRC), and are joined together to form an output signal ŝ. The output signal ŝ contains the reconstructions of the transmitted symbols, as estimated in the receiver.

The method of operation of the baseband section, as illustrated in FIG. 2, of a RAKE receiver structure according to the invention will be explained in more detail in the following text.

The baseband or intermediate frequency data r can be produced on the input side in the normal way, for example by a non-illustrated heterodyne stage. This contains, for example, a radio-frequency mixing stage which produces analog in-phase (I) and quadrature (Q) signal components from a signal which is received via an antenna, and down-mixes these signal components by frequency mixing to a suitable intermediate frequency, or to baseband. The down-mixed analog I and Q signal components are digitized by analog/digital converters. The digitization process is carried out, for example, at a sampling rate of 2/T_{c}, that is to say by way of example at about 8 MHz, with the individual chips of the spreading codes that are used for CDMA multiple access being separated.

The digitized I and Q signal components are then smoothed, in a manner which is likewise known, by a digital low-pass filter and, if necessary, their frequencies are corrected by a frequency correction unit.

The splitting of the sample values (data r) which are produced in this way into the signal components r_{F1}, r_{F2}, . . . , r_{F8} for the individual RAKE fingers is carried out under the control of the search and synchronization unit SE, by use of the path information ADD_{P}.

In order to assist understanding of the invention, the principle of a conventional RAKE receiver will be described at this point.

This principle assumes each RAKE finger is associated with one, and with only one, path (“subchannel”) through the air interface. Therefore, sample values are read on a path-related basis from the input memory IN_RAM by use of the path information ADD_{P}, and the corresponding data items r_{F1}, r_{F2}, . . . , r_{F8} are supplied to the individual RAKE fingers.

The RAKE fingers are then synchronized on a path-specific basis. For this purpose, the synchronization information sync that is emitted from the search and synchronization unit SE contains coarse and fine synchronization signals for each RAKE finger. The coarse synchronization signals represent individual time-controlled read instructions for the buffer stores S, and result in coarse synchronization of the individual RAKE fingers, for example to an accuracy of Tc. The fine synchronization is in each case carried out by the interpolators I, by interpolation of the sample values in the respective RAKE fingers as a function of individual interpolation instructions. The interpolation instructions (fine synchronization signals) are determined, for example, by an early/late correlator in the search and synchronization unit SE.

The process of interpolation of the sample values results in a reduction in the sampling rate in each RAKE finger to 1/Tc, that is to say each chip is represented by one signal value. The signals downstream from the interpolators I are synchronous with an accuracy of at least Tc/2.

In the JD-RAKE structure according to the invention, the RAKE fingers are, in contrast, not associated with specific paths through the air interface. Instead of path-specific synchronization, a fixed relative time offset of in each case one symbol time duration, that is to say Q chips, is set between each finger. This may be done by the memories S (in this case the RAKE fingers receive the same data r-_{F1}, r_{F2}, . . . , r_{F8}), or the time offsets can be provided by calling data from the input memory IN_RAM with an appropriate time offset. Only the first (“earliest”) finger need be synchronized on a path-related basis, and the synchronization of the other fingers is then oriented on this finger.

The signal processing according to the invention in the RAKE fingers will be analyzed in the following text.

The number of RAKE fingers in the RAKE finger section RF that are active for equalization of the received signal is determined by the control and assessment unit SB. The energy levels of the signal sequences that are associated with the individual fingers and are offset symbol by symbol in time are estimated in the control and assessment unit SB. Therefore, the energy level of chip sequence elements of length Q in the channel are in each case estimated, starting with the first tap of the channel. The energy level estimation is carried out with the aid of the channel impulse responses that are estimated by the channel estimator CE.

Furthermore, information about the quality of service achieved, for example information in order to determine the BER or a value of the BER that has already been determined in another functional unit, is signaled to the control and assessment unit SB. Various known methods are available for determination of information about the quality of service that has been achieved, for example this can be obtained during the channel decoding process, possibly in the course of block-by-block turbo decoding.

The RAKE fingers are selected on the basis of the determined energy levels in the signal sequences. The signal sequences with the highest energy levels are used for equalization.

The number of RAKE fingers that must be connected for an adequate detection quality depends on the determined quality of service, expressed, for example, by the BER. If the determined BER is above a required nominal value, further RAKE fingers must be connected in order to improve the quality of service. In the converse situation, that is to say when the estimated BER is below the nominal value of the required BER, one or more RAKE fingers may be disconnected.

In the example described here, the disconnection process is carried out via the deactivation device DEAK and the switching device SM. At the same time, a signal is passed to the calculation unit CU to inform it that it is no longer necessary to calculate the equalizer coefficients for the RAKE fingers that have been disconnected. As a consequence of this, the corresponding multipliers in the weighting unit WG can also be deactivated.

The described method (determination of the selection and of the number of active RAKE fingers) is carried out continually and repeatedly in a processing loop, so that up-to-date details (total number, finger numbers) about the active RAKE fingers that are required are always available. This takes account of the time variance in the reception conditions that occurs in mobile radio.

It is evident from the above description that the number of RAKE fingers that have been activated and deactivated in the RAKE finger section RF changes. In order to avoid an unnecessarily high level of hardware complexity associated with this, and for other reasons as well, the RAKE fingers may be multiplexed, in a manner that is not illustrated, in the RAKE finger section RF. For example (as illustrated), eight actual RAKE fingers and quadruple multiplication of this hardware structure allow a total number of 32 RAKE fingers (of which 24 are virtual RAKE fingers).

A further aspect is that variable spreading factors can be used, for example, in UMTS, as well as in other CDMA system standards. Since the multipliers M in the weighting unit WG carry out chip-by-chip multiplication for multi-subscriber equalization (that is to say each chip of a RAKE finger signal is multiplied by an equalizer coefficient that is determined by the calculation unit CU), and each multiplication process must be carried out on the basis of complex values (a complex-value multiplication corresponds to four real multiplications), multiplexing of the individual multipliers M within the weighting unit WG may, furthermore, be advantageous within the RAKE finger section RF. In this case, a demultiplexer circuit is disposed, in a manner that is not illustrated, in the signal path downstream from the multipliers M. For example, 16 hardware multipliers M may be provided, with each multiplier M having the capability to process signals from a maximum of two (of the 32 multiplexed) RAKE fingers.

The use of a RAKE receiver for carrying out JD equalization is, as has already been mentioned, based on the fact that the system matrix for a JD transmission system can be mapped onto the system matrix of a RAKE receiver which is oversampled Q times. This will now be explained in the following text.

A transmission channel for the k-th subscriber is described in the chip clock channel model, represented in the matrix vector formalization, by a matrix A_{G}^{(k)} of dimension Wₛ.Qx(Lₛ+Wₛ31 1), which describes both the transmitter-end signal processing by multiplication of spreading codes and scrambling codes by the data symbols s to be transmitted as well as the signal distortion suffered during transmission via the air interface. Lₛ denotes the channel length in symbols, that is to say the channel memory in the symbol clock channel model, and Wₛ denotes the (selectable) number of symbols taken into account for the equalization process. A superscript T denotes the transposed vector or the transposed matrix, while underscores indicate that a variable is a complex value.

A sequence comprising Lₛ+Wₛ−1 data symbols

$$\{ {\underline{s}}_{n - {L}_{s} + 1}^{k} , … , {\underline{s}}_{n}^{k} , … , {\underline{s}}_{n + {W}_{s} - 1}^{k} \}$$

to be transmitted for the k-th subscriber is described in the vector matrix formalism by the (column) vector

$${\underline{s}}_{n}^{( k )} = {( {\underline{s}}_{n - {L}_{s} + 1}^{k} … {\underline{s}}_{n + {W}_{s} - 1}^{k} )}^{T}$$

of dimension (Lₛ+Wₛ−1)×1 for the n-th time step.

With regard to all K subscribers,

$${\underline{s}}_{n} = {( {\underline{s}}_{n}^{( 1 ) T} … {\underline{s}}_{n}^{( k ) T} … {\underline{s}}_{n}^{( K ) T} )}^{T} \qquad ( 1 )$$

forms the so-called “combined” vector for all the transmitted data symbols, with respect to the n-th time step. Its dimension is K·(Lₛ+Wₛ−1)×1.

The transmitted data symbols are spread-coded, are each transmitted via two or more paths to the receiver, and are equalized by JD there.

The equation for the reconstruction

$${\underline{\hat{s}}}_{n}^{k}$$

of the data symbol which is transmitted by the k-th subscriber relating to the time step n is, in the receiver:

$$\begin{matrix}{\underline{\hat{s}}}_{n}^{( k )} = {\underline{m}}^{( k )} {\underline{r}}_{n} \\ where {\underline{r}}_{n} = {\underline{A}}_{G} {\underline{s}}_{n}\end{matrix} \qquad ( 2 )$$

In this case, the overall multi-subscriber system containing K subscribers (including spreading codings and signal distortion which occurs during the signal transmission) is described by the so-called multi-subscriber system matrix A_{G} whose dimension is Wₛ·Q×K(Lₛ+Wₛ−1).

The vector rₙ represents the received data that is returned to all the subscribers using the chip timing. The receiver-end JD equalization of the received data for the k-th subscriber is provided in this model by an equalizer vector m^{(k)}, whose dimension is 1×Wₛ·Q and which is calculated on the basis of the estimated channel coefficients by the calculation unit CU.

The Wₛ·Q elements of the equalizer vector m^{(k)} are the equalizer coefficients for the k-th subscriber.

The calculation rule for the equalizer vector m^{(k)} is dependent on the chosen equalizer algorithm. This will be described later for the case of ZF equalization.

The multi-subscriber system matrix A_{G} is obtained in the following manner from system matrices

$${\underline{A}}_{G}^{( k )}$$

whose dimension is Wₛ·Q×(Lₛ+Wₛ−1) for the individual subscribers:

$${\underline{A}}_{G} = ⌊ {\underline{A}}_{G}^{( 1 )} {\underline{A}}_{G}^{( 2 )} … {\underline{A}}_{G}^{( K )} ⌋ \qquad ( 3 )$$

The subscriber system matrices

$${\underline{A}}_{G}^{( k )}$$

are defined by:

$${\underline{A}}_{G}^{( 1 )} = [ \begin{matrix}[ {\underline{A}}^{′ ( k )} ] 0 … 0 \\ 0 [ {\underline{A}}^{′ ( k )} ] 0 … 0 \\ 00 [ {\underline{A}}^{′ ( k )} ] 0 … 0 \\ 0 … 0 [ {\underline{A}}^{′ ( k )} ] \end{matrix} ] \qquad ( 4 )$$

where A′^{(k)} is, in the general case, a matrix whose dimension is Q×Lₛ and which is shown here, to assist the representation form, for the special case of Lₛ=2 (that is to say for the dimension Q×2).

$${\underline{A}}^{′ ( k )} = [ \begin{matrix}{\underline{a}}_{Q + 1}^{( k )} & {\underline{a}}_{1}^{( k )} \\ {\underline{a}}_{Q + 2}^{( k )} & {\underline{a}}_{2}^{( k )} \\ ⋮ & ⋮ \\ {\underline{a}}_{Q + L - 1}^{( k )} & {\underline{a}}_{L - 1}^{( k )} \\ 0 & {\underline{a}}_{L}^{( k )} \\ ⋮ & ⋮ \\ 0 & {\underline{a}}_{Q}^{( k )}\end{matrix} ] \qquad ( 5 )$$

The elements of the matrices A′^{(k)} are obtained from the respective spreading codes for the subscribers and from the channel characteristics:

a^{(k)}=C′^{(k)}h^{(k)T} (6)

In this case,

$${\underline{a}}^{( k )} = {( {\underline{a}}_{1}^{( k )} … {\underline{a}}_{Q + L - 1}^{( k )} )}^{T}$$

is a vector whose dimension is (Q+L−1)×1 and C′^{(k)} is a matrix which is obtained from the spreading code C_{SP} for the k-th subscriber under consideration, and in this case is denoted

$${\underline{c}}^{( k )} = ( {\underline{c}}_{1}^{k} … {\underline{ c}}_{Q}^{k} ) :$$

$${C}^{′ ( k )} = [ \begin{matrix}{\underline{c}}_{1}^{k} & 0 & ⋯ & 0 \\ {\underline{c}}_{2}^{k} & {\underline{c}}_{1}^{k} & & ⋮ \\ ⋮ & {\underline{c}}_{2}^{k} & & \\ {\underline{c}}_{Q}^{k} & & & ⋮ \\ 0 & {\underline{c}}_{Q}^{k} & & 0 \\ ⋮ & \cdot & & {\underline{c}}_{1}^{k} \\ & & \cdot & {\underline{c}}_{2}^{k} \\ ⋮ & & & ⋮ \\ 0 & ⋯ & 0 & {\underline{c}}_{Q}^{k}\end{matrix} ] \qquad ( 7 )$$

whose dimension is (Q+L−1)×L. In this case, L denotes the channel length in chips in the chip clock channel model.

$${\underline{h}}^{( k )} = {( {\underline{h}}_{1}^{k} … {\underline{h}}_{L}^{k} )}^{T}$$

is the (column) vector, which is formed from the L channel impulse responses

$${\underline{h}}_{1}^{k} , {\underline{h}}_{2}^{k} , … , {\underline{h}}_{L}^{k}$$

for the k-th subscriber.

In order to simplify the mathematical representation, it is assumed that no scrambling code is used.

An analogous description of a transmission system (but related to block data transmission) is known in the prior art and is described in detail on pages 188-215 of the book entitled “Analyse und Entwurf digitaler Mobilfunksysteme” [Analysis and Design of Digital Mobile Radio Systems] by P. Jung, B. G. Teubner Verlag Stuttgart, 1997. This reference is incorporated herein in the subject matter of the present document.

It is clear that the “equalizer” m^{(k)} which is required for calculation of a transmitted data symbol of the k-th subscriber contains Q “sub-equalizers”, each having a length of Wₛ. Therefore a RAKE receiver which is operated with Q-times oversampling is required for JD equalization. Furthermore, the above analysis clearly shows that the despreading is an integral component of the equalization process.

In the case of ZF multi-subscriber equalization, the equalizer coefficients (that is to say the elements of the equalizer vector m^{(k)}) are calculated by solving the equation system

m^{(k)}A_{G}=ζⱼ (8)

In this case, ζⱼ is a 1×K·(Lₛ+Wₛ−1) (row) vector, which predetermines the ZF condition for a specific (k-th) subscriber. The ZF vector ζⱼ can be represented as follows:

ζⱼ=(0 . . . 010 . . . 0) (9)

where the 1 in the j-th position indicates

j=(k−1) (Lₛ+Wₛ−1)+1, . . . , k(Lₛ+Wₛ−1).

Another algorithm which can be used for multi-subscriber equalization is MMSE and its DF (decision feedback) variants.

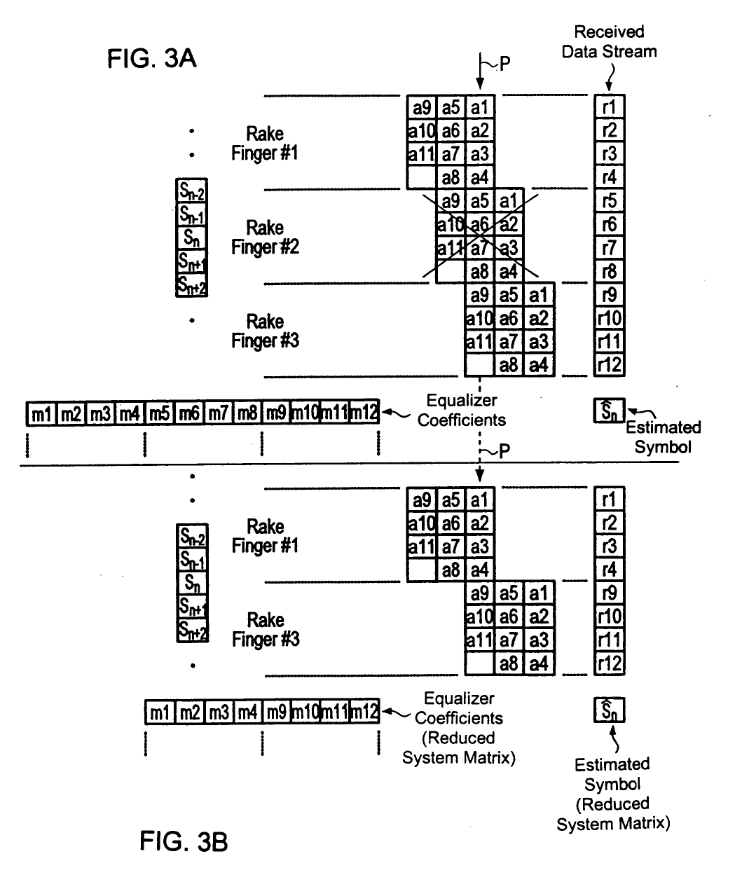

FIG. 3A shows the calculation of

$${\underline{\hat{s}}}_{n}^{k}$$

for any given subscriber k, referred to in the following text as ŝₙ, for Q=4, Wₛ=3, Lₛ=3 and K=1, by the RAKE receiver structure on the basis of a representation of a detail of the system matrix A_{G}, of the equalizer coefficients m1 to m12, of the data items Sₙ₋₂ to Sₙ₊₂ which are transmitted by the subscriber (at the symbol clock rate), of the received data items r1 to r12 (at the chip clock rate) and of the data symbol ŝₙ which is estimated for the n-th time step (underscores are ignored in FIG. 3A). The RAKE finger #1 processes the first signal sequence, which contains Q chips, the RAKE finger #2 processes the second Q data items, which are delayed by Q·T_{c}, etc. Therefore the input signal to each RAKE finger is a signal whose symbol rate has been oversampled by Q times. Each sample value contains the same information with regard to the transmitted data symbol, but contains different information with regard to the spreading code that is used and to the transmission channel.

The instantaneous energy levels of the signals which are processed in the RAKE fingers are obtained as the sum of the respective matrix elements in the column identified by the arrow P, that is to say for the RAKE finger #1 as the sum of the matrix elements a1, a2, a3, a4, for the RAKE finger #2 as the sum of the matrix elements a5, a6, a7, a8, and for the RAKE finger #3 as the sum of the matrix elements a9, a10, a11. A measure for the interference in each RAKE finger is given by the sum of the matrix elements in the remaining columns (that is to say, for the RAKE finger #1, as the sum of the matrix elements a9, a10, a11, a5, a6, a7, a8; for the RAKE finger #2 as the sum of the matrix elements a9, a10, a11, a1, a2, a3, a4; and for the RAKE finger #3 as the sum of the matrix elements a5, a6, a7, a8, a1, a2, a3, a4). The instantaneous energy level is, as already mentioned, determined in each RAKE finger by measurement over a sequence of Q chips. The energy measurement is thus carried out at the symbol clock rate.

If a low energy level is measured in the RAKE finger #2 and, on the other hand, a sufficiently good quality of service is determined, the RAKE finger #2 is disconnected. This is indicated in FIG. 3A by the deletion lines through the corresponding matrix section.

The dimension of the system matrix is reduced by the deletion of the matrix section associated with the RAKE finger #2. FIG. 3B shows a detail of the system matrix that corresponds to FIG. 3A, but after it has been reduced. The received data items r5, r6, r7, r8 are no longer considered for the equalization process and, in consequence, the equalizer vector is shortened by the corresponding vector elements.

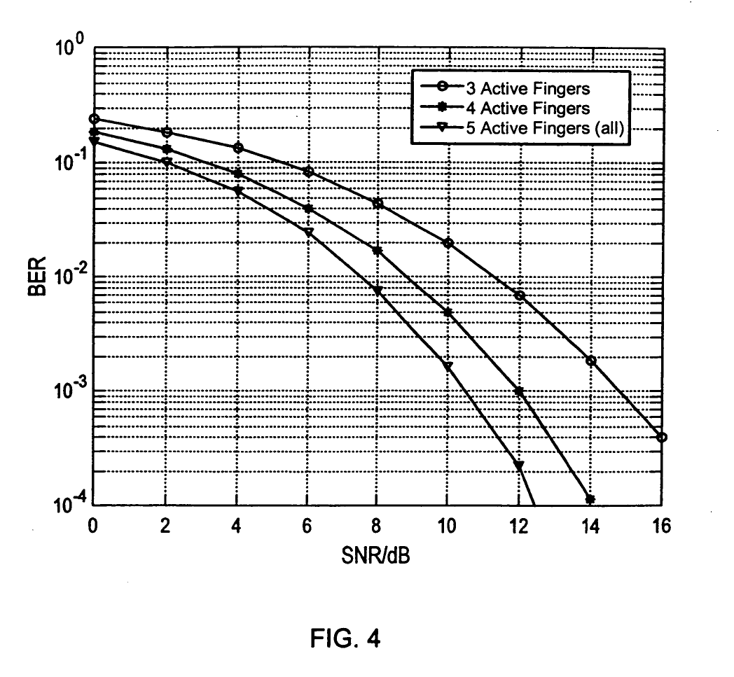

FIG. 4 shows the raw bit error rate (BER) that was obtained in a simulation of the RAKE receiver as a function of the signal-to-noise ratio (SNR). The simulation was carried out for the channel length Lₛ=5 and for three to five active RAKE fingers in a RAKE receiver containing a total of five fingers. The channel was simulated on the basis of the CODIT MIC model.

FIG. 4 shows that, in the area of a signal-to-noise ratio of between 6 and 10 dB, the reduction in power is about 1.5 dB when four fingers are activated, and is about 4 dB when three fingers are activated. These results are acceptable for signals with error-protection coding.

The ZF equalization and one possible method for solving equation 8 by Cholesky decomposition are described in detail in German Patent Application DE 101 06 391.1, and are incorporated, by reference, herein in the contents of the present document.

We claim:

1. A method for multi-subscriber detection using a RAKE receiver structure having a fixed time offset between the RAKE fingers, which comprises the step of:
mapping a multi-subscriber system matrix onto the RAKE receiver structure by allocating each of the RAKE fingers to a defined section of the multi-subscriber system matrix; and
deactivating at least one of the RAKE fingers for reducing power consumption of the RAKE receiver structure during operation.

2. The method according to claim 1, which further comprises:
measuring energy levels of signals associated with the RAKE fingers; and
determining which of the RAKE fingers are to be deactivated in dependence on the energy levels measured.

3. The method according to claim 1, which further comprises:
determining a value of an assessment variable which is characteristic of a quality of service of a detected signal; and
determining a number of active RAKE fingers in dependence on a the value of the assessment variable.

4. The method according to claim 3, which further comprises forming the assessment variable as a bit error rate (BER).

5. The method according to claim 1, wherein the method is used in a mobile station in a mobile radio system.

6. The method according to claim 1, which further comprises carrying out ZF multi-subscriber equalization on received signals.

7. The method according to claim 1, which further comprises carrying out MMSE multi-subscriber equalization on received signals.

8. A RAKE receiver structure for multi-subscriber detection, comprising:
rake fingers; and
means for deactivating at least one of said RAKE fingers for reducing power consumption during operation.

9. The RAKE receiver structure according claim 8, further comprising:
means for measuring energy levels of signals associated with said RAKE fingers; and
a means for determining which of said RAKE fingers are to be deactivated, in dependence on the energy levels measured.

10. The RAKE receiver structure according to claim 8, further comprising:
means for determining an assessment variable which is characteristic of a quality of service of a detected signal; and
means for determining which of said RAKE fingers are to be deactivated, in dependence on a determined assessment variable.

11. The RAKE receiver structure according to claim 8, further comprising means for calculating multi-subscriber equalizer coefficients for ZF equalization of received signals.

12. The RAKE receiver structure according to claim 8, further comprising means for calculating multi-subscriber equalizer coefficients for MMSE equalization of received signals.

13. A RAKE receiver structure for multi-subscriber detection, comprising:
rake fingers; and
a switch connected to and deactivating at least one of said RAKE fingers for reducing power consumption during operation.

14. The RAKE receiver structure according claim 13, further comprising:
a channel estimator coupled to said rake fingers; and
a control and assessment unit coupled to said rake fingers, said channel estimator and said control and assessment unit measuring energy levels of signals associated with said RAKE fingers, said control and assessment unit determining which of said RAKE fingers are to be deactivated, in dependence on the energy levels measured.

15. The RAKE receiver structure according to claim 13, further comprising:
means for determining an assessment variable which is characteristic of a quality of service of a detected signal; and
a control and assessment unit coupled to said rake fingers for determining which of said RAKE fingers are to be deactivated, in dependence on a determined assessment variable.

16. The RAKE receiver structure according to claim 13, further comprising a calculating unit coupled to said rake fingers for calculating multi-subscriber equalizer coefficients for ZF equalization of received signals.

17. The RAKE receiver structure according to claim 13, further comprising a calculating unit coupled to said rake fingers for calculating multi-subscriber equalizer coefficients for MMSE equalization of received signals.
